(19) United States
(12) Patent Application Publication
(10) Pub. No.: US 2007/0227658 A1
(43) Pub. Date: Oct. 4, 2007

(54) CONTROL DEVICE FOR CONTROLLING SUBSTRATE PROCESSING APPARATUS AND METHOD THEREFOR

(75) Inventors: Takeshi Yokouchi, Miyagi (JP); Fumiko Yagi, Miyagi (JP)

Correspondence Address: OBLON, SPIVAK, MCCLELLAND, MAIER & NEUSTADT, P.C., 1940 DUKE STREET, ALEXANDRIA, VA, 22314, US

(73) Assignee: TOKYO ELECTRON LIMITED, Tokyo (JP)

(21) Appl. No.: 11/692,426

(22) Filed: Mar. 28, 2007

Related U.S. Application Data
(60) Provisional application No. 60/789,883, filed on Apr. 7, 2006.

(30) Foreign Application Priority Data
Mar. 29, 2006 (JP) 2006-091102

(51) Int. Cl. G06F 19/00; H01L 21/306; C23F 1/00; B05C 11/00

(52) U.S. Cl. 156/345.27; 156/345.24; 118/666; 700/95

(57) ABSTRACT

An EC 200 includes a substrate processing execution unit 280 that executes an etching process on a product substrate, a dummy processing execution unit 275 that executes a dummy process on a dummy substrate and a decision-making unit 270 that makes a decision as to whether the dummy process is to be executed based upon a temperature-related condition. The decision-making unit 270 obtains temperature-related information to be used to regulate the atmosphere inside the individual PM processing containers and makes a decision as to whether the temperature status inside each processing container is regulated based upon the obtained temperature information. If it is decided by the decision-making unit 270 that the temperature status in the processing container has been regulated, the substrate processing execution unit 280 executes the etching process on a product substrate without executing the dummy process.

### CROSS REFERENCE TO RELATED APPLICATIONS

The present invention contains subject matter related to Japanese Patent Application No. 2006-091102 filed on Mar. 29, 2006 and Provisional Application No. 60/789,883 filed on Apr. 7, 2006, the entire contents of which are incorporated herein by reference.

### BACKGROUND OF THE INVENTION

1. Field of the Invention

The present invention relates to a control device that controls a substrate processing apparatus that executes a processing on a product substrate, a control method to be adopted in the substrate processing apparatus and a recording medium having stored therein a control program. More specifically, it relates to a control device that makes a decision as to whether or not to execute dummy processing in order to regulate the state inside the processing container, a control method adopted by the control device and a recording medium having stored therein a control program in conformance to which the control is executed.

2. Description of the Related Art

Substrate processing such as CVD (chemical vapor deposition) processing, etching or ashing is normally executed based upon a procedure defined in a preset recipe in a substrate processing apparatus. As films are formed on numerous substrates through CVD processing, films are also gradually deposited on the inner wall of the processing container. In addition, as a film formed on a substrate is ground through etching, reaction products reacted by the plasma are deposited on the inner walls of the processing container during an etching process. Then, as the atmosphere within the processing container is repeatedly heated and cooled, the foreign matter present on the inner wall of the processing container becomes flaked off or separated from the inner wall and particles of foreign matter fall onto the substrate. The presence of such particles on the substrate is undesirable since it degrades the performance of the processed product.

Accordingly, there are technologies known in the related art that address the particle-related issues by cleaning the inside of the processing container on a regular basis and seasoning the atmosphere within the processing container following the cleaning process so as to automatically regulate the atmosphere. During this seasoning process, dummy processing is executed on a non-product substrate based upon a procedure indicated in a preset recipe and, as a result, the states in the substrate processing apparatus become regulated.

### SUMMARY OF THE INVENTION

However, such dummy processing should not be necessary as long as the states within the processing container are already stable. In addition, it is safe to assume that states other than the temperature, such as the pressure, do not need to be taken into consideration. The rationale for this assumption is as follows. Namely, the temperature is the least responsive condition among the various processing conditions. For instance, after the temperature setting at a heater or the like installed in the substrate processing apparatus is adjusted to the selected processing condition, it takes a significant length of time before the temperature inside the processing container stabilizes at the temperature selected to match the optimal processing conditions.

For this reason, if the states within the processing container are not stable, the temperature must first be adjusted to the value matching the selected processing conditions and the operation must wait in standby while the actual temperature inside the processing container gradually shifts to the selected temperature level, prior to processing a product substrate. In other words, if the states inside the processing container are not yet regulated, the temperature condition, the least responsive of the conditions, must be controlled in advance. From this viewpoint, the benefit of executing dummy processing in order to regulate the states (in particular the temperature) within the processing container is significant if the states inside the processing container are unstable.

Processing conditions other than the temperature, such as the pressure and power settings, are relatively responsive. For instance, once the flow rate of the gas, the quantity of the gas displacement, the quantity of power being supplied are adjusted to values matching the required processing conditions, the corresponding states within the processing container reach the target values almost instantly. This means that executing dummy processing prior to the substrate processing in order to regulate processing conditions other than the temperature would be a waste of resources such as the various types of energy and materials used in the dummy processing. Furthermore, since no product can be manufactured while executing the unnecessary dummy processing, the throughput would be lowered to result in low productivity.

The issues discussed above are addressed in the present invention by providing a control device for a substrate processing apparatus, which makes a decision as to whether or not to execute dummy processing in order to regulate states inside the processing container based upon a temperature-related condition, a control method adopted in the control device and a control program in conformance to which the control is executed.

Namely, the issues discussed above are addressed in an embodiment of the present invention by providing a control device for a substrate processing apparatus, which includes a substrate processing execution unit that executes a predetermined processing on a product substrate and a dummy processing execution unit that executes dummy processing on a non-product substrate. The control device further includes a decision-making unit that obtains information related to a temperature to be used to regulate the atmosphere within a processing container included in the substrate processing apparatus and makes a decision as to whether or not a temperature status within the processing container is already regulated based upon the obtained temperature information. The substrate processing execution unit executes the predetermined processing on the product substrate without allowing the dummy processing execution unit to execute the dummy processing in case that the decision-making unit determines that the temperature status in the processing container is already regulated.

Before executing the predetermined processing such as etching on a product substrate, the atmosphere inside the processing container needs to be regulated so as to achieve states matching the optimal processing conditions. Since the actual temperature within the processing container, in particular, takes a significant length of time to reach the target value as explained earlier, the benefit of executing the dummy processing so as to regulate the temperature status within the processing container prior to the product substrate processing is considerable.

Processing conditions other than the temperature, such as the pressure and power settings, are relatively responsive. For instance, once the flow rate of the gas, the quantity of the gas displacement, the quantity of power being supplied are adjusted to values matching the required processing conditions, the corresponding states within the processing container reach the target values almost instantly. For this reason, executing dummy processing, which takes a considerable length of time, in order to pre-regulate states other than the temperature inside the processing container at significant cost does not make sense.

Accordingly, if it is decided that the temperature status inside the processing container is already regulated, the predetermined processing such as etching is executed on the product substrate without executing dummy processing in the above construction. Thus, wasteful consumption of resources including various types of energy such as the gas and the power and the materials used in the dummy processing can be minimized. Furthermore, the time that would otherwise be spent executing dummy processing can be more efficiently utilized for actual production of products. Thus, better efficiency is achieved in energy consumption and, at the same time, productivity can be greatly improved through an improvement in throughput.

The control device may further comprise a storage unit in which a single recipe or a plurality of recipes to be used when processing substrates is stored. the decision-making unit may make a decision as to whether or not the temperature status in the processing container is regulated based upon a first decision-making condition for comparing a temperature setting indicated in a recipe used when processing an immediately preceding product substrate with a temperature setting indicated in a recipe to be used in the next product substrate among the recipes stored in the storage unit.

The decision-making unit may make a decision as to whether or not the temperature status in the processing container is regulated based upon a second decision-making condition for comparing a value calculated in correspondence to a power setting indicated in a recipe used when processing a previous product substrate with a value of a power setting indicated in a recipe to be used when processing the next product substrate in addition to the first decision-making condition. The value calculated in correspondence to the power setting indicated in the recipe used when processing the previous product substrate mentioned above may be an average value of power settings indicated in a plurality of recipes used to process a plurality of substrates in a lot having been processed most recently or it may be the value of the power setting indicated in the recipe used to process the most recently processed substrate.

The substrate processing apparatus may include a temperature sensor that detects the temperature inside the processing container and the decision-making unit may obtain the temperature inside the processing container detected by the temperature sensor and may make a decision as to whether or not the temperature status in the processing container is regulated based upon a third decision-making condition for comparing the obtained temperature in the processing container with the temperature setting indicated in a recipe to be used when processing the next product substrate.

In conjunction with the temperature sensor described above, a decision as to whether or not the temperature status in the processing container is regulated is made based upon the difference between the actual temperature inside the processing container and the temperature setting indicated in the recipe. By comparing the actual temperature with the temperature setting indicated in the recipe to be used for the next process, as described above, an accurate decision can be made with regard to the temperature status inside the processing container based upon the actual states inside the processing container. This ultimately makes it possible to make a decision as to whether or not to execute dummy processing with a higher level of accuracy.

It is to be noted that while the sensor should preferably detect the temperature in the vicinity of the upper electrode inside the processing container, no specific restrictions apply with regard to the location of the temperature detection and that any detection value, such as a detection value indicating the temperature in the vicinity of the lower electrode, the temperature at the stage on which the substrate is placed, the temperature at the side wall of the processing container or the temperature setting at the heater may be used as long as it indicates the temperature status inside the processing container.

In addition, the control device may further comprise a continuous lot feed instruction unit that issues a continuous lot feed instruction so as to allow a second lot constituted with another product substrate group to be continuously processed in succession to a first lot constituted with a product substrate group that includes the product substrate undergoing processing. The decision-making unit in such a control device may make a decision based upon the second decision-making condition or conditions including the second decision-making condition, only when the continuous lot feed instruction unit has issued a continuous lot feed instruction.

The control device may further comprise a discontinuous lot feed instruction unit that issues a discontinuous lot feed instruction so as to discontinuously execute processing for a given lot when a lot constituted with a product substrate group that includes a product substrate undergoing processing does not exist. In response to a discontinuous lot feed instruction issued by the discontinuous lot feed instruction unit, the dummy processing execution unit may execute dummy processing on a non-product substrate before the predetermined processing is executed on product substrates in the discontinuously fed lot, without allowing the decision-making unit to first make the decision.

It is reasonable to assume that when lot processing is executed discontinuously, a relatively long time will elapse between the processing time point at which the immediately preceding lot (product substrates) was processed and the processing time point at which the next lot is processed. For instance, such discontinuous processing may be executed on a lot fed after executing maintenance work on the substrate processing apparatus. Under such circumstances, the states in the processing container will have been disrupted and destabilized. For this reason, it is necessary to regulate the states inside the processing container before processing a product substrate. The temperature condition in particular must be controlled well in advance for the reason explained earlier.

Accordingly, in response to a discontinuous lot feed instruction, dummy processing is executed on a non-product substrate before executing processing such as etching on a product substrate without waiting for decision results to be provided by the decision-making unit, in the present invention. By executing dummy processing, the conditions inside the processing container including the temperature status can be regulated with a high level of reliability. This, in turn, enables accurate execution of the processing on the product substrate.

The decision-making unit may make a decision as to whether or not the temperature status inside the processing container is regulated based upon at least any one of decision-making condition among the first decision-making condition, the second decision-making condition and the third decision-making condition in correspondence to a parameter indicating a specified dummy processing execution condition.

For instance, if a continuous lot feed instruction has been issued by the continuous lot feed instruction unit and “continuous lot feed” has been specified in the parameter as the dummy processing execution condition, the decision-making unit may make a decision as to whether or not the temperature status inside the processing container is regulated based upon the third decision-making condition.

In addition, if a continuous lot feed instruction has been issued by the continuous lot feed instruction unit and “continuous lot feed” has not been specified in the parameter as a dummy processing execution condition, the decision-making unit may make a decision as to whether or not the temperature status in the processing container is regulated based upon the first decision-making condition and the second decision-making condition.

Alternatively, if a continuous lot feed instruction has been issued by the continuous lot feed instruction unit and “continuous lot feed” has not been specified in the parameter as a dummy processing execution condition, the decision-making unit may make a decision as to whether or not the temperature status in the processing container is regulated based upon the first decision-making condition, the second decision-making condition and the third decision-making condition.

If a discontinuous lot feed instruction has been issued by the discontinuous lot feed instruction unit and “discontinuous lot feed” has been specified in the parameter as a dummy processing execution condition, the dummy processing execution unit may execute dummy processing on a non-product before executing the predetermined processing on the discontinuously fed product substrates without allowing the decision-making unit to make the decision.

In other words, if the parameter specifies that dummy processing be executed in the event that “discontinuous lot feed” is specified, the dummy processing is executed unconditionally. As a result, the atmosphere in the processing container can be regulated to a stable state with a high level of reliability prior to the product substrate processing.

When a discontinuous lot feed instruction has been issued by the discontinuous lot feed instruction unit and “discontinuous lot feed” has not been specified in the parameter as the dummy processing execution condition, the decision-making unit may make a decision as to whether or not the temperature status inside the processing container is regulated based upon the first decision-making condition and the third decision-making condition.

The issues discussed earlier are also addressed in another embodiment of the present invention by providing a control method for controlling a substrate processing apparatus that executes a predetermined processing on a product substrate. The method includes steps for obtaining temperature-related information to be used to regulate the atmosphere inside a processing container, making a decision as to whether or not a temperature status inside the processing container has been regulated based upon the temperature information having been obtained and executing the predetermined processing on a product substrate without executing dummy processing on a non-product substrate if the temperature status inside the processing container is determined to be regulated.

The issues discussed earlier are further addressed in yet another embodiment of the present invention by providing a computer-readable recording medium having stored therein a control program to be used to control a substrate processing apparatus that executes a module for obtaining temperature-related information to be used to regulate the atmosphere inside a processing container, a module for making a decision as to whether or not a temperature status inside the processing container is regulated based upon the obtained temperature information, and a module for executing the predetermined processing on a product substrate without executing dummy processing on a non-product substrate in case that the temperature status inside the processing container is decided to be regulated.

According to the present embodiment, if the temperature status inside the processing container is determined to be regulated, the predetermined processing is executed on the product substrate without executing the dummy processing. Thus, the wasteful consumption of resources such as energy and materials that have been used in the execution of unnecessary dummy processing in the related art, can be eliminated. In addition, the time spent on the execution of dummy processing in the related art can now be allocated for execution of the actual product substrate processing. Consequently, better efficiency in energy utilization is achieved and, at the same time, the productivity is greatly improved through an improvement in throughput.

As explained above, the present invention allows a predetermined processing to be executed on a product substrate by skipping dummy processing whenever the temperature status inside the processing container is judged to have been regulated based upon a temperature-related condition.

### BRIEF DESCRIPTION OF THE DRAWINGS

FIG. 1 shows the substrate processing system achieved in an embodiment of the present invention;

FIG. 2 presents a diagram of the hardware configuration adopted in the EC in the embodiment of the present invention;

FIG. 3 presents a diagram of the hardware configuration adopted in the PMs in the embodiment of the present invention;

FIG. 4 is a longitudinal sectional view of a PM achieved in the embodiment of the present invention;

FIG. 5 is a functional block diagram of the EC achieved in the embodiment of the present invention;

FIG. 6 illustrates the continuous lot feed and the discontinuous lot feed, as implemented in the embodiment of the present invention;

FIG. 7 presents a flowchart of the lot processing routine executed in the embodiment of the present invention;

FIG. 8 presents a flowchart of the dummy decision-making/substrate processing routine (continuous lot feed) executed in the embodiment of the present invention;

FIG. 9 presents an example of the recipe A used for the immediately preceding processing in the embodiment of the present invention;

FIG. 10 presents an example of the recipe B to be used next in the embodiment of the present invention;

FIG. 11 presents another example of the recipe B to be used next in the embodiment of the present invention;

FIG. 12 presents a flowchart of the dummy decision-making/substrate processing routine (discontinuous lot feed) executed in the embodiment of the present invention;

FIG. 13 presents yet another example of the recipe B to be used next in the embodiment of the present invention;

FIG. 14 is a longitudinal sectional view of another PM that may be used in an embodiment of the present invention; and

FIG. 15 is a longitudinal sectional view of another PM that may be used in an embodiment of the present invention.

### DETAILED DESCRIPTION OF THE EMBODIMENTS

The following is a detailed explanation of preferred embodiments of the present invention, given in reference to the attached drawings it is to be noted that in the following explanation and the attached drawings, the same reference numerals are assigned to components having identical structural features and functions to preclude the necessity for a repeated explanation thereof.

In addition, the description in the specification is provided by assuming that 1 mTorr is equal to (10⁻³×101325/760) Pa and that 1 sccm is equal to (10⁻⁶/60) m³/sec.

### First Embodiment

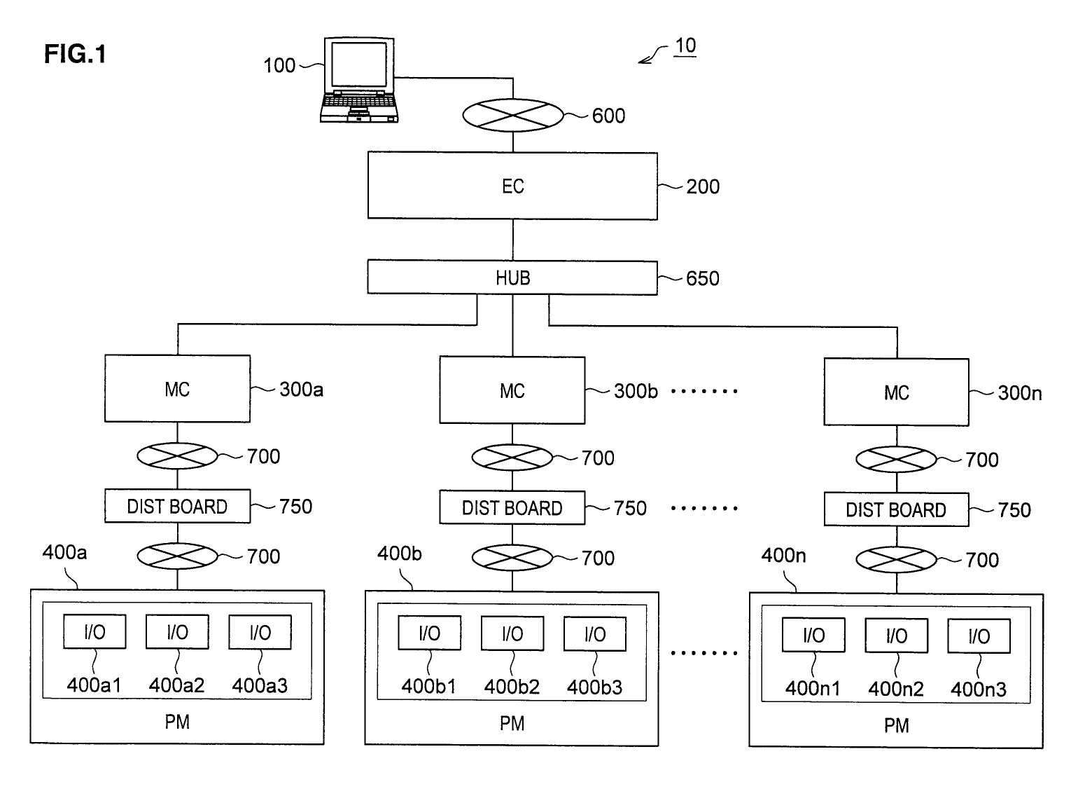

First, the substrate processing system that includes the control device achieved in the first embodiment of the present invention is described in reference to FIG. 1. It is to be noted that the following explanation is provided by assuming that the system achieved in the embodiment executes an etching process.

### (Substrate Processing System)

The overall structure adopted in the substrate processing system is first explained in reference to FIG. 1.

A substrate processing system 10 comprises an MES (manufacturing execution system) 100, an EC (equipment controller) 200, a switching hub 650, nMCs (module controllers) 300a˜300n, nDIST (distribution) boards 750 and nPMs (process modules) 400a˜400n.

The MES 100, constituted with an information processing apparatus (e.g. a PC (personal computer)), executes overall management of the manufacturing processes executed in the plant where the plurality of PMs 400 are installed and also sends/receives necessary information with a main system (not shown). The MES 100 is connected with the EC 200 via a network 600 such as a LAN (local area network).

The EC executes integrated control on the processes executed by the plurality of PMs 400 by controlling the plurality of MCs 300 connected thereto via the switching hub 650. More specifically, based upon a recipe indicating the specific method for processing the processing target wafer W, the EC 200 transmits a control signal for MCs 300 with given timing. The switching hub 650 selects a specific MC among the MCs 300a˜300n as the recipient of the control signal having been transmitted from the EC 200. Based upon the control signal transmitted thereto, the recipient MC 300 executes control so as to execute a predetermined processing (etching in the embodiment) on a wafer W having been transferred into the corresponding PM. In this configuration, the EC 200 functions as a master-side device and the MCs 300 function as slave-side devices. It is to be noted that while the EC 200 also has a function of making a decision as to whether or not to execute dummy processing before the wafer processing, this function is to be described in detailed later.

The MCs 300 are each connected at a DIST board 750 to a plurality of I/O ports (400a1˜400a3, 400b1˜400b3 . . . or 400n˜400n3) at the corresponding PM 400 via a GHOST (general high-speed optimum scalable transceiver) network 700. The GHOST network 700 is controlled by an LSI (referred to as GHOST) mounted at the MC board of the corresponding MC 300. In this configuration, the MC 300 functions as a master-side device and the I/O ports function as slave-side devices. The MC 300 outputs an actuator drive signal corresponding to the drive signal transmitted from the EC 200, to one of the IO ports.

As the actuator drive signal transmitted from the MC 300 is transmitted through the I/O port to a specific unit (PM) at the corresponding PM 400, the unit is driven in conformance to the command issued by the EC and a signal output from the specific unit is transmitted through the I/O port to the MC 300.

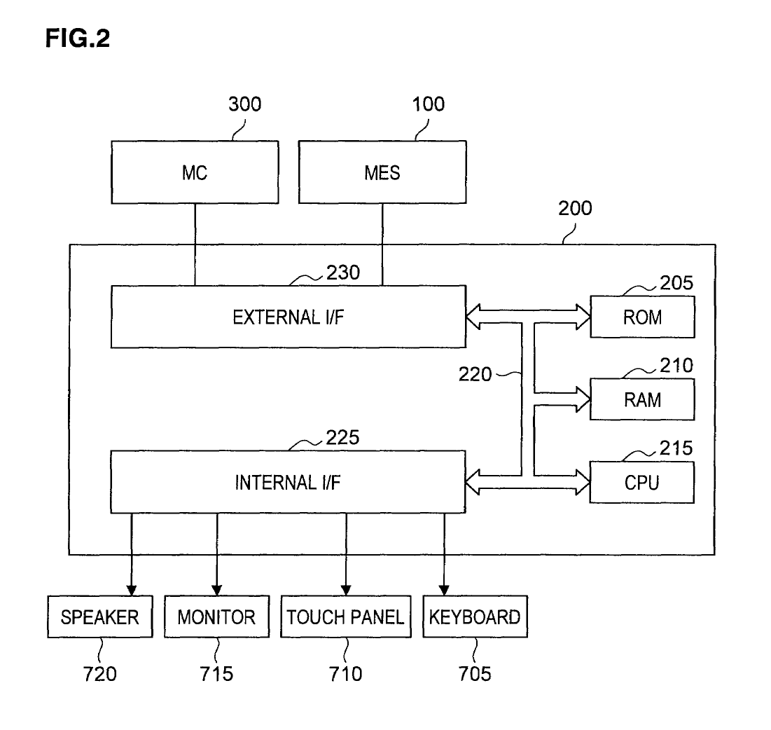

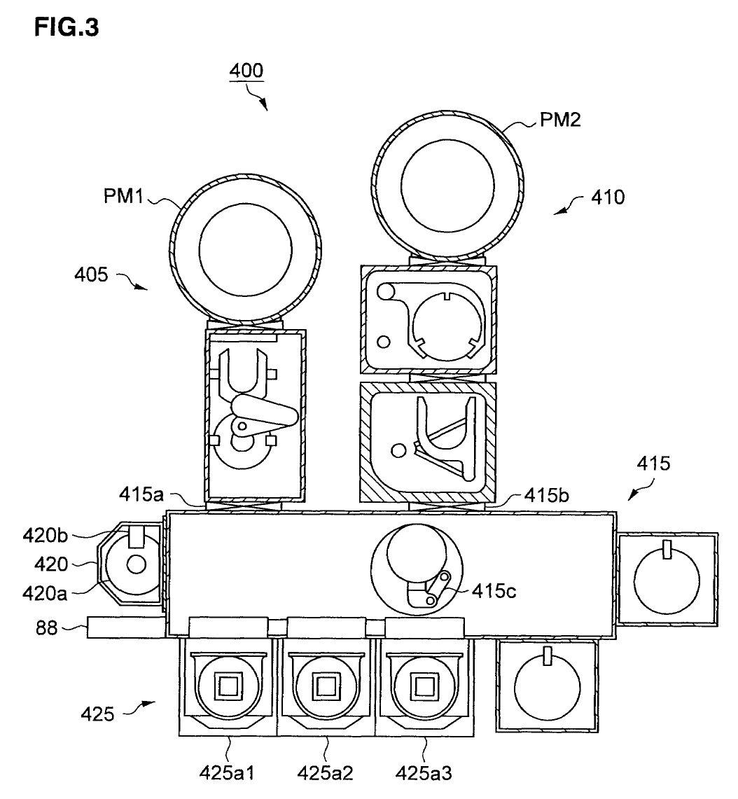

Next, the hardware configurations assumed in the EC 200 and the PMs 400 are explained in reference to FIGS. 2 and 3 respectively. It is to be noted that while illustrations of the hardware configurations of the MES 100 and the MCs 300 are not provided, they adopt configurations similar to that of the EC 200.

### (Hardware Configuration of the EC)

As shown in FIG. 2, the EC 200 includes a ROM 205, a RAM 210, a CPU 215, a bus 220, an internal interface (internal I/F) 225 and an external interface (external I/F) 230.

Basic programs executed in the EC 200, a program started up when an error has occurred, and the like are recorded in the ROM 205. Various programs, recipes and the like are stored in the RAM 210. In a recipe used for an etching process, the procedure to be followed when etching a product wafer (glass wafer) and the processing conditions (e.g., a temperature setting) to be selected for the etching process are defined. In a recipe used for a dummy process, a procedure to be followed when executing the dummy process on a non-product wafer (dummy wafer) and the processing conditions to be selected for the dummy process are defined. It is to be noted that the ROM 205 and the RAM 210 each simply represent an example of a storage device and that any type of storage device such as an EEPROM, an optical disk, a magneto optical disk, a hard disk or the like may be used instead.

The CPU 215 controls the etching process executed on product wafers and also executes the dummy process on a non-product wafer whenever necessary. The bus 220 forms a path through which information is transmitted among the various devices.

A parameter (data) indicating a dummy process execution condition, for instance, are input to the internal interface 225 from a keyboard 705 or a touch panel 710 in response to an operation performed by the operator. In addition, information is output from the internal interface 225 to a monitor 715 and a speaker 720. The external interface 230 sends/receives data with the MES 100 and the MCs 300.

### (Hardware Configuration of the PM System)

As shown in FIG. 3, each PM 400 (equivalent to a substrate processing apparatus) includes a first processing ship 405, a second processing ship 410, a transfer unit 415, an alignment mechanism 420 and a cassette stage 425.

The first processing ship 405 includes a PM (process module) 1 that executes a reactive ion etching (RIE) process on a wafer by using plasma. The second processing ship 410, disposed in parallel to the first processing ship 405, includes a PM 2 that executes a COR (chemical oxide removal) process and a PHT (post heat treatment) process on the wafer having undergone the RIE process.

The transfer unit 415, which is a rectangular transfer chamber, is connected with the first processing ship 405 and the second processing ship 410 respectively via a gate valve 415a and a gate valve 415b. A transfer arm 415c installed in the transfer unit 415 transfers a wafer having been transferred thereto to the first processing ship 405 or the second processing ship 410 by opening/closing the gate valves 415a or 415b so as to sustain the required level of airtightness in each unit.

At one end of the transfer unit 415, the alignment mechanism 420 that aligns the wafer W is disposed. The alignment mechanism 420 aligns the wafer W to the desired position by detecting the state of the peripheral edge of the wafer W with an optical sensor 420b while a rotating stage 420a on which the wafer W is placed rotates.

The cassette stage 425 is installed at a side wall of the transfer unit 415, with three cassette containers 425a1˜425a3 set at the cassette stage 425. Up to, for instance, 25 wafers W can be housed over multiple stages in each cassette container 425a.

### (Internal Structure and Functions of Each PM)

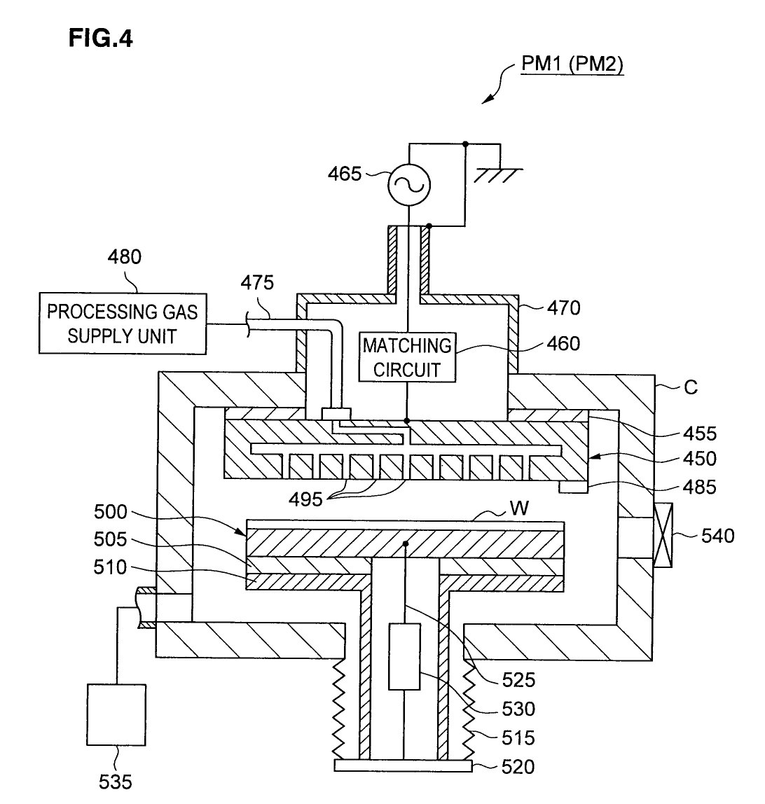

Next, the internal structure and the functions of each of the PMs engaged in the etching process are explained in reference to the schematic longitudinal sectional view of the PM1 (PM2) in FIG. 4.

The PM1 (PM2) includes a processing container C assuming the shape of an angular tube with openings formed at a substantial center at its ceiling and at a substantial center at its bottom. The processing container C may be constituted of, for instance, aluminum having been surface-treated through anodization.

An upper electrode 450 is installed on the upper side within the processing container. The upper electrode 450 is electrically isolated from the processing container C by an insulator 455 disposed over the edge of the opening formed at the ceiling of the processing container C. A high-frequency power source 465 is connected via a matching circuit 460 to the upper electrode 450. A matching box 470, disposed around the matching circuit 460, constitutes a grounded casing for the matching circuit 460.

A processing gas supply unit 480 is connected via a gas supply passage 475 to the upper electrode 460 so that a desired type of gas supplied from the processing gas supply unit 480 is supplied into the processing container C through a plurality of gas injection holes 495. In other words, the upper electrode 450 also functions as a gas showerhead. A temperature sensor 485 is mounted at the upper electrode 450. The temperature sensor 485 detects the temperature in the vicinity of the upper electrode 450 as the temperature reading inside the processing container.

In the lower space within the processing container, a lower electrode 500 is installed. The lower electrode 500 also functions as a susceptor on which the wafer W is placed. The lower electrode 500 is supported by a supporting member 510 which is installed via an insulator 505. The lower electrode 500 is thus electrically isolated from the processing container C.

One end of a bellows 515 is attached to an area near the outer circumference of the opening formed at the bottom surface of the processing container C. An elevator plate 520 is locked onto the other end of the bellows 515. By adopting this structure, it is ensured that the opening at the bottom surface of the processing container C is sealed with the bellows 515 and the elevator plate 520. In addition, the lower electrode 500 moves up/down together with the bellows 515 and the elevator plate 520 so as to adjust the position at which the wafer W is placed to the optimal height for the processing.

An impedance adjustment unit 530 and the elevator plate 520 are connected to the lower electrode 500 via a conductive passage 525. The upper electrode 450 and the lower electrode 500 are respectively equivalent to a cathode electrode and an anode electrode. In the process module adopting this structure, the pressure inside the processing container is lowered until a desired level of vacuum is achieved via an evacuation mechanism 535, the gas supplied into the processing chamber where the substrate W having been transferred thereto while sustaining the required level of airtightness by opening/closing a gate valve 540 is present, is raised to plasma with high-frequency power applied thereto, and the substrate W is etched as desired with the plasma thus generated.

### (Functional Structure of the EC)

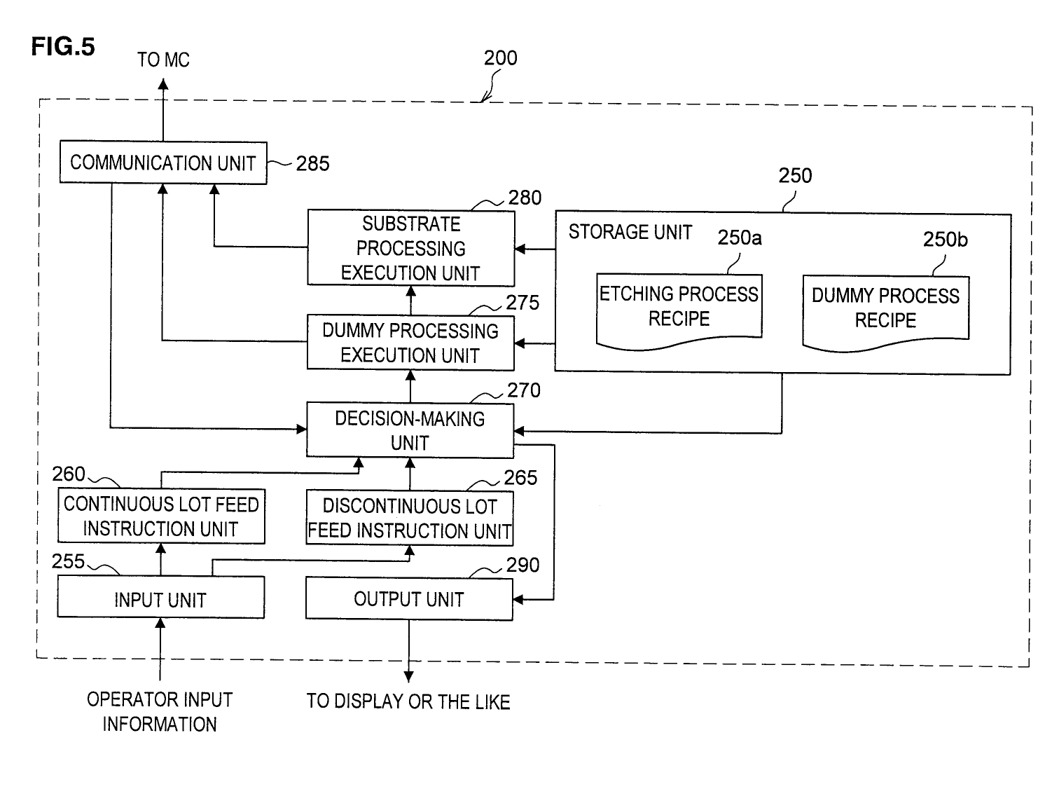

Next, the various functions of the EC 200 are explained in reference to FIG. 5 presenting a functional block diagram of the EC 200. The EC 200 has functions indicated by functional blocks corresponding to a storage unit 250, an input unit 255, a continuous lot feed instruction unit 260, a discontinuous lot feed instruction unit 265, a decision-making unit 270, a dummy processing execution unit 275, a substrate processing execution unit 280, a communication unit 285 and an output unit 290.

In the storage unit 250, a single recipe or a plurality of recipes to be used when processing substrates or dummy substrates are stored. Namely, an etching process recipe 250a indicating a procedure to be followed when etching a substrate W and a dummy process recipe 250b indicating a procedure to be followed when dummy-processing a dummy substrate are stored in the storage unit 250. Information such as a parameter indicating a dummy processing execution condition, specified by the operator is input to the input unit 255.

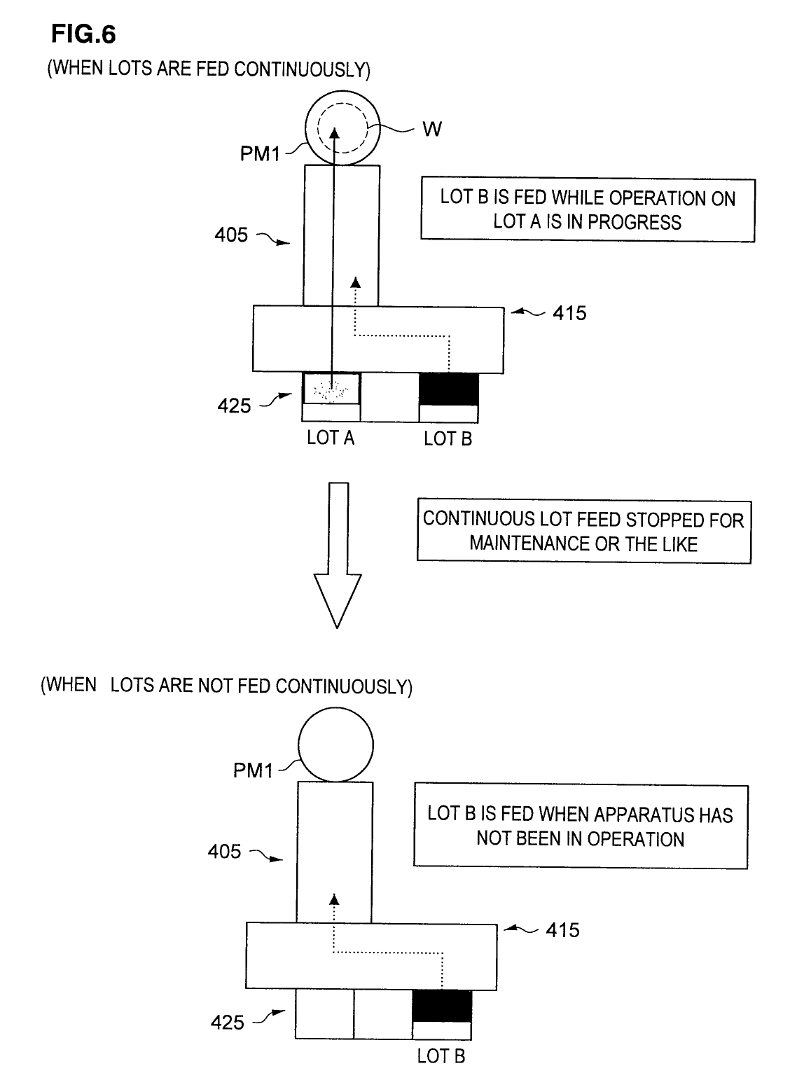

The continuous lot feed instruction unit 260 issues an instruction for a continuous lot feed when a first lot (constituted with a product substrate group that includes the substrate W currently undergoing an etching process) is present, so as to allow a second lot constituted with another product substrate group to be processed in succession to the first lot. For instance, let us consider a situation in which 25 substrates W in a lot A are sequentially transferred into the PM1 to undergo the etching process at the PM1 as illustrated on the upper side of FIG. 6. If the operator requests feed (processing) of a lot B while the lot A is being processed, the continuous lot feed instruction unit 260 issues a “continuous lot feed” instruction to the decision-making unit 270 in response. Under normal circumstances, in which the plant is engaged in operation 24 hours a day, this “continuous lot feed” instruction is usually issued when lot processing is requested.

The discontinuous lot feed unit 265 issues a discontinuous lot feed instruction when there is no lot constituted with a product substrate group that includes a substrate W currently undergoing an etching process so as to discontinuously process a given lot. For instance, when there is no substrate W having been transferred into the PM1 and currently undergoing an etching process (i.e., when the apparatus is in a non-operating state) and the operator requests feed (processing) of a new lot B as illustrated on the lower side of FIG. 6, the discontinuous lot feed instruction unit 265 issues a “discontinuous lot feed” instruction to the decision-making unit 270 in response. The “discontinuous lot feed” instruction may be issued when, for instance, processing for a new lot is requested after an interval following maintenance work executed on the PM to clean the PM by stopping a continuous lot feed, or when the processing of a new lot is requested after the atmosphere inside the PM has become destabilized following a relatively long down time at the PM due to, for instance, a natural disaster or a major accident.

The decision-making unit 270 obtains temperature-related information to be used to regulate the atmosphere inside the processing container and makes a decision as to whether or not the temperature status in the processing container C has been regulated based upon the obtained temperature information. The temperature-related information used to determine whether or not the atmosphere inside the processing container is regulated may be, for instance, information indicating the actual temperature inside the processing container (the temperature at the upper electrode 450 in this example) detected by the temperature sensor 485. While it is desirable that the temperature near the upper electrode 450 be detected via the temperature sensor 485, no specific restrictions apply with regard to the location of the temperature detection, as long as a value indicating the temperature status inside the processing container, such as the temperature near the lower electrode 500, the temperature at the stage on which the substrate is placed, the temperature on a side wall of the processing container or the temperature setting selected at the heater, is detected.

Alternatively, a temperature setting T defined in the etching process recipe 250a to be used when etching the next substrate W or a temperature setting Trold defined in the etching process recipe 250a having been used for the most recent etching process may be used as the information related to the temperature inside the processing container.

The dummy processing execution unit 275 executes a dummy process on a dummy substrate inside the processing container. More specifically, the dummy processing execution unit 275 executes a predetermined processing on a non-product dummy substrate based upon the procedure defined in the dummy process recipe 250b so as to regulate the states inside the processing container to match the processing conditions prior to the execution of an etching process on a product substrate.

The substrate processing execution unit 280 executes a predetermined processing (an etching process in the embodiment) on the substrate W inside the processing container based upon the procedure defined in the etching process recipe 250a.

Upon receiving a command from the dummy processing execution unit 275, the communication unit 285 transmits to the MC 300 a control signal in response to which the dummy process is executed on the dummy substrate having been transferred into the PM. The MC 300, in turn, transmits a drive signal corresponding to the control signal to various actuators within the PM, and as the individual actuators are engaged in operation in response to the drive signal, the states within the PM are regulated to match the processing conditions prior to the execution of the etching process on a product substrate.

In addition, upon receiving a command from the substrate processing execution unit 280, the communication unit 285 transmits to the MC 300 a control signal in response to which the etching process is executed on the product substrate having been transferred into the PM. The MC 300, in turn, transmits a drive signal corresponding to the control signal to the various actuators within the PM, and as the individual actuators are engaged in operation in response to the drive signal, the product substrate in the PM is etched. If any error occurs during a given process, the output unit 290 issues a warning for the operator by indicating the error at the monitor 715 and also outputs necessary information to the speaker 720 or the like.

It is to be noted that the various functions of the EC 200 described above are, in fact, achieved as the CPU 215 executes a program having processing procedures for achieving these functions or as an IC (not shown) for achieving these functions are realized. For instance, the functions of the continuous lot feed instruction unit 260, the discontinuous lot feed instruction unit 265, the decision-making unit 270, the dummy processing execution unit 275 and the substrate processing execution unit 280 are actually achieved in the embodiment as the CPU 215 or the like executes programs or recipes having the processing procedures for realizing these functions.

### (Operations of the EC)

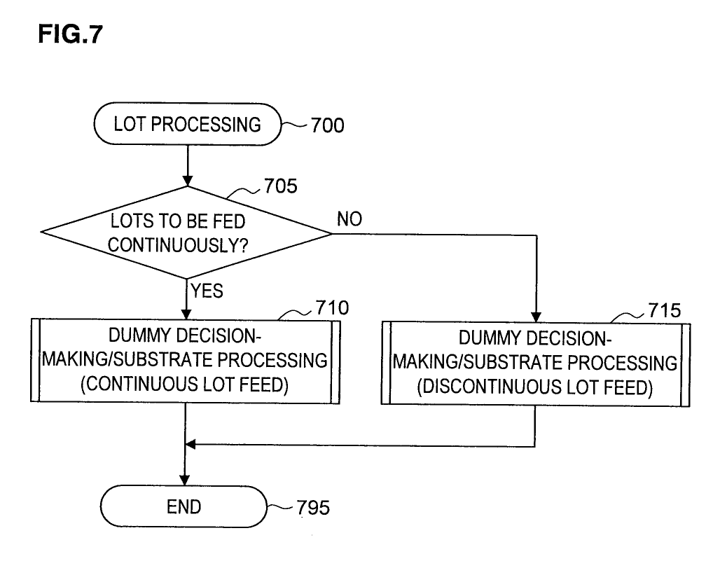

Next, lot processing (dummy decision-making/substrate processing) operations executed by the EC 200 are explained in reference to FIG. 7. FIG. 7 presents a flowchart (main routine) of the lot processing executed by the EC 200.

It is to be noted that before this processing starts, a parameter indicating the dummy processing execution condition will have been set to “continuous lot feed”, “discontinuous lot feed”, “continuous/discontinuous lot feed” or “no setting” in response to an operation performed by the operator. The operator selects “continuous lot feed” when he wishes to restrict the dummy process execution in conjunction with a continuous lot feed. The operator selects “discontinuous lot feed” when lots are not continuously fed (discontinuous lot feed) and the operator wishes to unconditionally execute the dummy process prior to the lot processing. The operator selects “continuous/discontinuous lot feed” when he wishes to both restrict the dummy process execution in conjunction with a continuous lot feed and to unconditionally execute the dummy process in conjunction with a discontinuous lot feed. “No setting” may be selected by the operator choosing normal execution of the dummy process or it may be set as a default value if the operator has not selected any other setting.

### (Lot Processing)

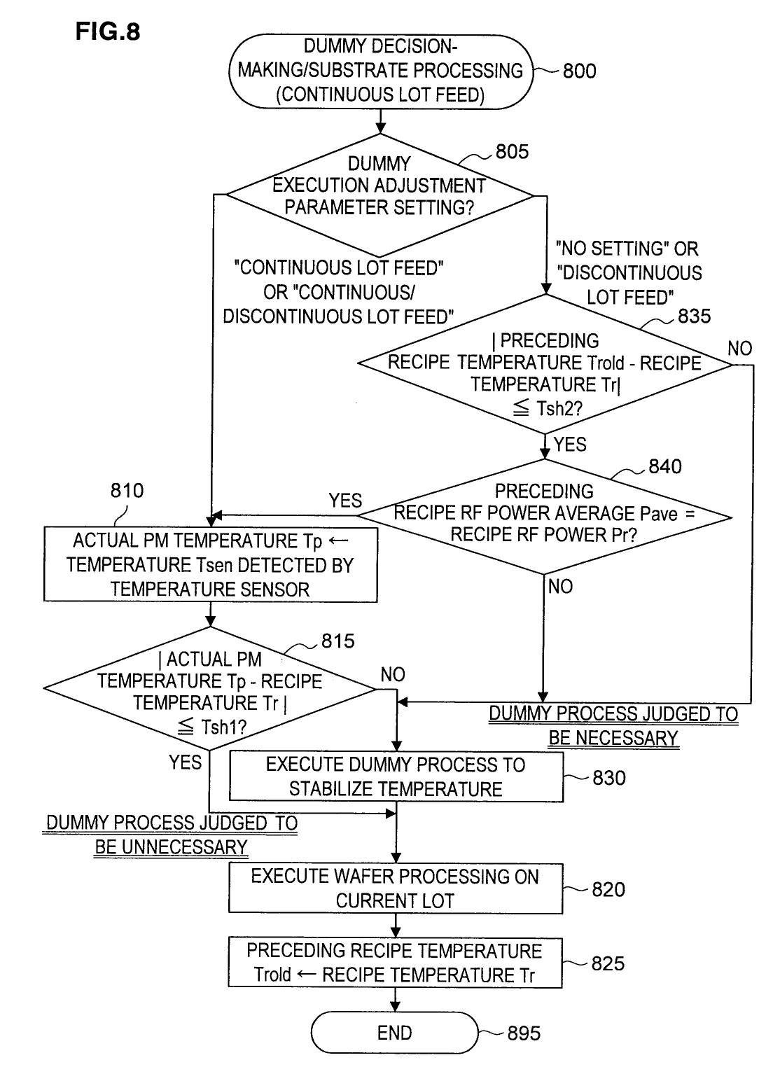

As the operator turns on a lot start button, the lot processing starts in step 700 in FIG. 7. The operation proceeds to step 705 in which the decision-making unit 270 makes a decision as to whether or not the relevant lot has been fed through a continuous feed. If a continuous lot feed instruction has been issued by the continuous lot feed instruction unit 260, the decision-making unit 270 judges that the relevant lot has been fed through a continuous feed and, in this case, the operation proceeds to step 710 to execute dummy decision-making/substrate processing (see FIG. 8) for the continuous lot feed. Subsequently, the operation proceeds to step 795 to end the processing.

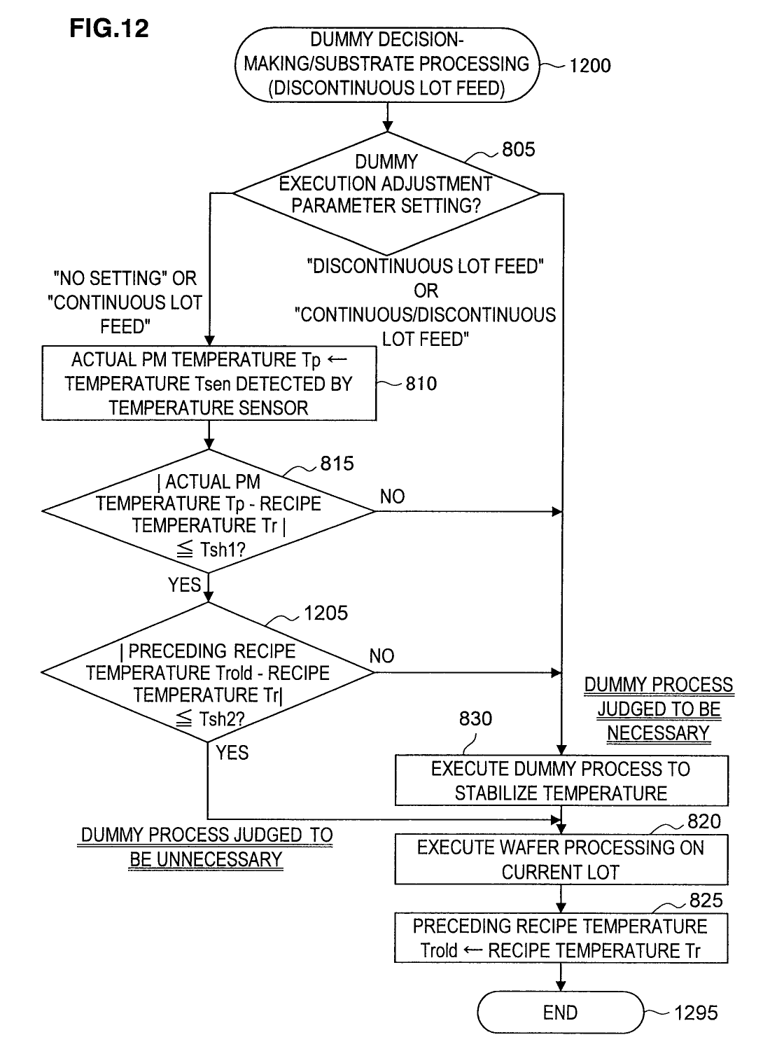

If, on the other hand, a discontinuous lot feed instruction has been issued by the discontinuous lot feed instruction unit 265, the decision-making unit 270 judges that the relevant lot has been fed through a discontinuous feed, and in this case the operation proceeds to step 715 to execute dummy decision-making/substrate processing (see FIG. 12) for the discontinuous lot feed. Then the operation proceeds to step 795 to end the processing.

### (Dummy Decision-Making/Substrate Processing: Continuous Lot Feed)

The dummy decision-making/substrate processing for the continuous lot feed, which is called up in step 710, is now explained in reference to the flowchart presented in FIG. 8. After the dummy decision-making/substrate processing for the continuous lot feed starts in step 800 in FIG. 8, the operation proceeds to step 805 in which the decision-making unit 270 determines the setting selected for a dummy operation adjustment parameter. If either “continuous lot feed” or “continuous/discontinuous lot feed” has been selected for the dummy operation adjustment parameter, the decision-making unit 270 judges that the operator wishes to restrict the dummy process execution and, in this case, the operation proceeds to step 810.

### (Parameter: Continuous Lot Feed or Continuous/Discontinuous Lot Feed)

More specifically, the decision-making unit 270 first stores the actual temperature Tsen inside the processing container detected by the temperature sensor 485 as an actual PM temperature Tp in step 810. Then, the operation proceeds to step 815 in which the decision-making unit 270 makes a decision as to whether or not the absolute value of the difference between the actual PM temperature Tp and the temperature setting (recipe temperature Tr) defined in the etching process recipe 250a to be used when processing the relevant lot (the substrate to be processed next) is equal to or less than a predetermined interlock Tsh1 (equivalent to the third decision-making condition).

If the absolute value of the difference between the actual PM temperature Tp and the recipe temperature Tr is equal to or less than the interlock Tsh1, the decision-making unit 270 judges that the dummy process does not need to be executed as the states inside the processing container are stable enough for execution of the etching process and, in this case, the operation proceeds to step 820. After the substrate processing execution unit 280 executes the etching process on the substrates in the target lot, the operation proceeds to step 825 to save the recipe temperature Tr as a preceding recipe temperature Trold. Then the operation proceeds to step 895 to end the processing.

If, on the other hand, the absolute value of the difference between the actual PM temperature Tp and the recipe temperature Tr is greater than the interlock Tsh1, the decision-making unit 270 judges that the dummy process needs to be executed as the temperature inside the processing container is not stable enough for execution of the etching process and, in this case, the operation proceeds to step 830. After the dummy processing execution unit 275 executes the dummy process on a dummy substrate and the operation proceeds to step 820, the substrate processing execution unit 280 executes the etching process on the substrate in the target lot, the operation proceeds to step 825 to save the recipe temperature Tr as the preceding recipe temperature Trold. The operation then proceeds to step 895 to end the processing.

### (Parameter: No Setting or Discontinuous Lot Feed)

Following the explanation provided above on the decision-making executed with regard to the dummy process when either “continuous lot feed” or “continuous/discontinuous lot feed” is judged to be selected as the dummy execution adjustment parameter in step 805, the decision-making executed with regard to the dummy process when either “no setting” or “discontinuous lot feed” is judged to be selected as the dummy execution adjustment parameter in step 805.

If it is decided in step 805 that either “no setting” or “discontinuous lot feed” has been selected as the dummy execution adjustment parameter, the operation proceeds to step 835 in which the decision-making unit 270 makes a decision as to whether or not the absolute value of the difference between the temperature setting Trold indicated in the recipe used when processing the immediately preceding substrate and the temperature setting Tr indicated in the recipe to be used when processing the next substrate is equal to or less than a predetermined interlock Tsh2 (equivalent to the first decision-making condition).

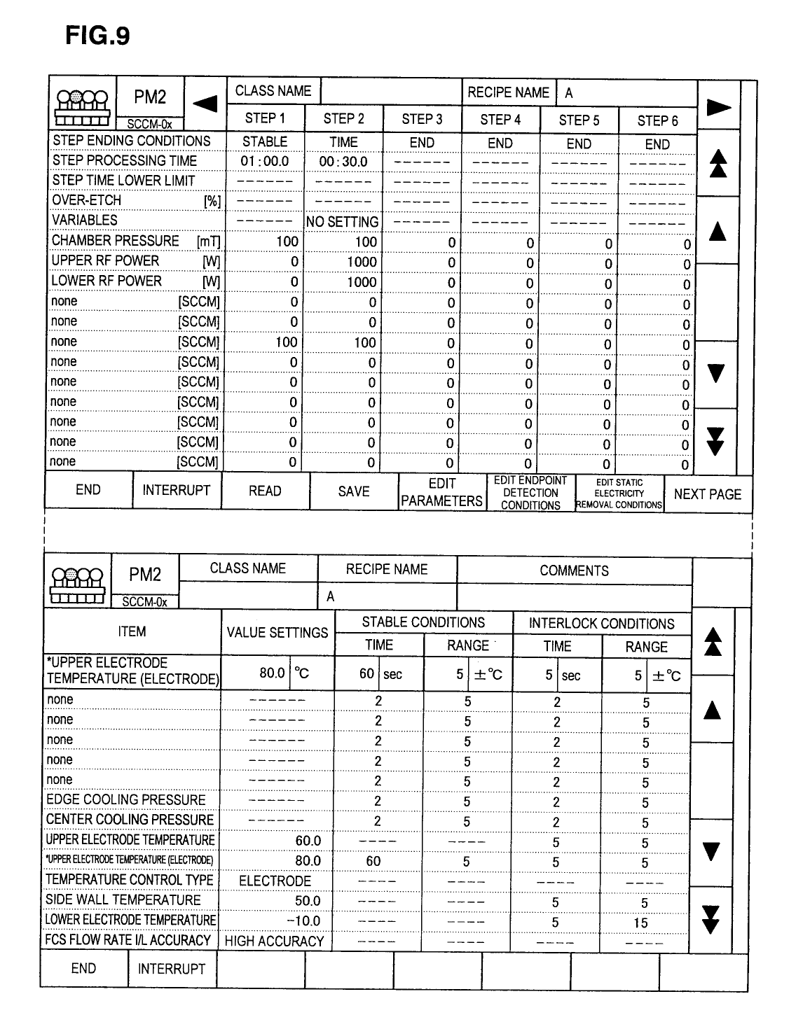

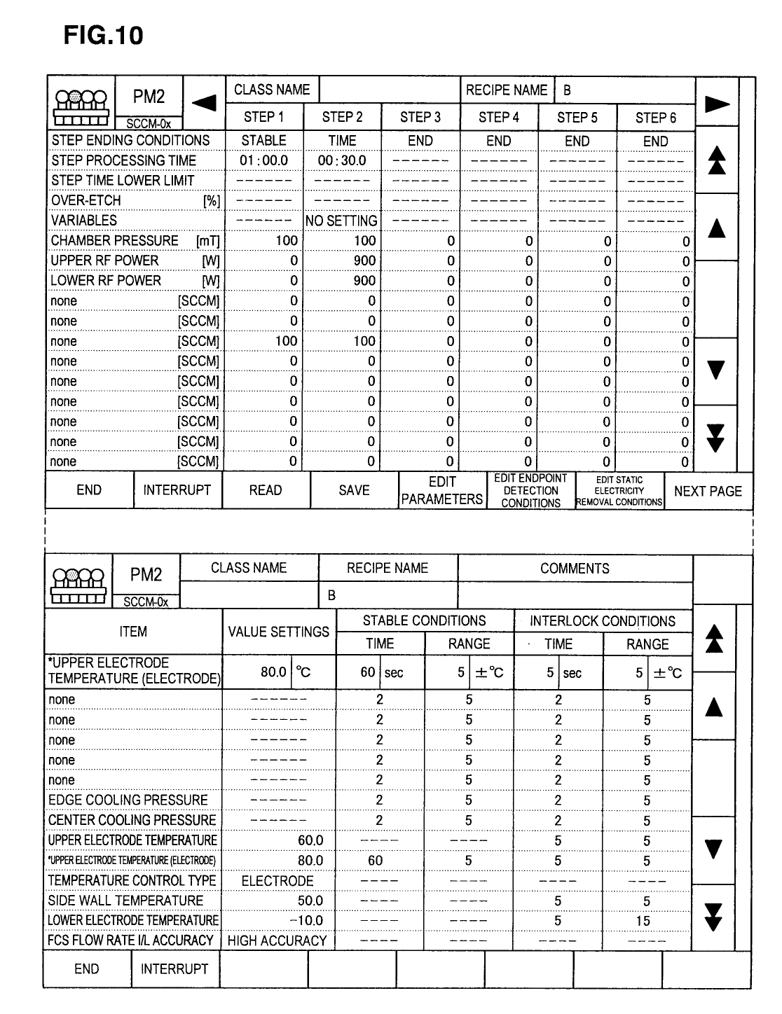

FIG. 9 presents an example of an etching process recipe A having been used when processing the immediately preceding lot, whereas FIG. 10 presents an example of an etching process recipe B to be used when processing the a subsequent lot. As indicated in the figures, the interlock Tsh2 is 5° C., the temperature setting (upper electrode temperature (electrode)) specified in the etching process recipe A is 80° C. and the temperature setting (upper electrode temperature (electrode)) specified in the etching process recipe B is also 80° C.

Under these circumstances, the difference between the temperature setting indicated in the etching process recipe A and the temperature setting indicated in the etching process recipe B is equal to or less than the interlock Tsh2 and, accordingly, the decision-making unit 270 makes an affirmative (“YES”) decision in step 835 to proceed to step 840 in which it makes a decision as to whether or not there is any difference between the average value Pave of the upper RF power values indicated in a single recipe or a plurality of recipes having been used while processing the preceding lot (while processing a plurality of substrates in the immediately preceding lot) (e.g., the upper RF power values indicated in recipes such as that shown in FIG. 9) and the RF power setting Pr indicated in the recipe to be used when processing the next substrate (e.g., the upper RF power value indicated in the recipe shown in FIG. 10) (equivalent to the second decision-making condition).

If the etching process recipe A is used when processing all the substrates in the preceding lot, the average value Pave of the upper RF power values indicated in the immediately preceding recipes is “1000 W”, as shown in FIG. 9. The upper RF power value Pr indicated in the recipe to be used next is “900 W”, as shown in FIG. 10, and thus, the average value Pave and the upper RF power value Pr are not equal to each other. Under these circumstances, the decision-making unit 270 judges that the states within the processing container have not been regulated and that the dummy process needs to be executed. Accordingly, the operation proceeds to step 830. After the dummy processing execution unit 275 executes the dummy process, the operation proceeds to step 820 in which the substrate processing execution unit 280 etches the substrates, and then the operation proceeds to step 825 to save the recipe temperature Tr (upper electrode temperature (electrode)), i.e., 80° C., as indicated in FIG. 10, as the preceding recipe temperature Trold, before the operation proceeds to step 895 to end the processing.

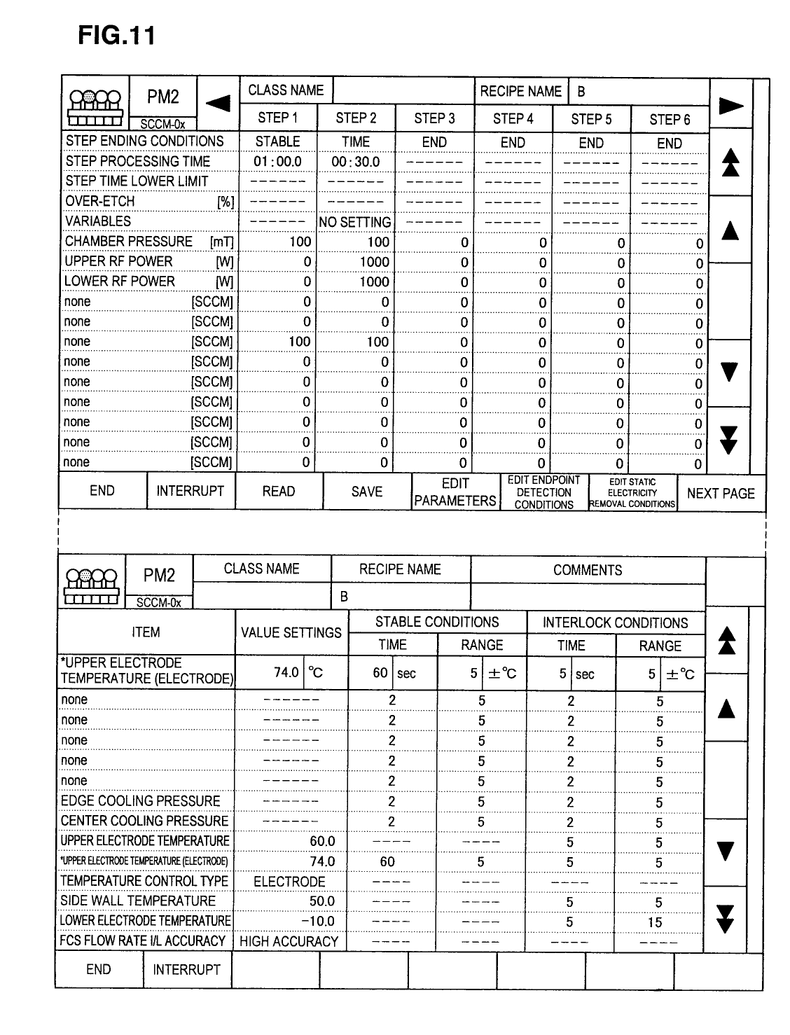

If, on the other hand, the temperature setting Trold (upper electrode temperature (electrode)) indicated in the etching process recipe A in FIG. 9, is 80° C. and the temperature setting Tr (upper electrode temperature (electrode)) indicated in the etching process recipe B is 74° C., as shown in FIG. 11, the difference between the temperature setting in the etching process recipe A and the temperature setting in the etching process recipe B is greater than the interlock Tsh2 (=5° C.). Accordingly, the decision-making unit 270 judges that the dummy process needs to be executed under these circumstances, and thus, a negative (“NO”) decision is made in step 835. In this case, the operation proceeds to step 830 immediately to execute the dummy process. Then, the etching process is executed in step 820, the operation proceeds to step 825 to save the recipe temperature Tr as the preceding recipe temperature Trold and afterwards, the operation proceeds to step 895 to end the processing.

In addition, if the absolute value of the difference between the temperature setting Trold indicated in the recipe having been used in the immediately preceding lot processing and the temperature setting Tr indicated in the recipe to be used in the subsequent lot processing is equal to or less than the interlock Tsh2 (=5° C.) (i.e., if the first decision-making condition is satisfied) and the average value Pave of the upper RF power values in the preceding recipes is equal to the upper RF power Pr in the recipe to be used subsequently (i.e., if the second decision-making condition is satisfied), the decision-making unit 270 proceeds to step 810. Then, if the decision-making unit 270 determines in step 815 following step 810 that the absolute value of the difference between the actual PM temperature Tp and the temperature setting (recipe temperature Tr) defined in the etching process recipe 250a to be used when processing the relevant lot is equal to or less than a predetermined interlock Tsh1 (i.e., if the third decision-making condition is satisfied), the decision-making unit 270 judges that no dummy process needs to be executed and step 820 and step 825 are executed, whereas if it is decided in step 815 that the third decision-making condition is not satisfied, the decision-making unit judges that the dummy process needs to be executed and step 820, step 825 and step 830 are executed, and then the processing sequence ends.

As described above, through the dummy decision-making/substrate processing executed in conjunction with a continuous lot feed in the embodiment, a decision is made as to whether or not the dummy process is to be executed based upon at least any one of; the first decision-making condition, the second decision-making condition and the third decision-making condition in correspondence to the selected parameter. If it is decided that a specific decision-making condition is satisfied, it is judged that the atmosphere in the processing container has stabilized to an extent at which a product substrate can be processed and, in such a case, the etching process is executed immediately without first executing the dummy process. Thus, the wasteful consumption of resources, including the high frequency power, the gas and dummy substrates that have been used in the execution of unnecessary dummy processing in the related art, can be eliminated. In addition, the time spent on the execution of dummy processing in the related art can be allocated for execution of the actual product substrate processing. Consequently, better efficiency in energy utilization is achieved and, at the same time, the productivity is greatly improved through an improvement in throughput.

It is to be noted that the power setting indicated in the recipe used when processing the most recent substrate, instead of the average value of the power settings indicated in a plurality of recipes used to process a plurality of substrates in the immediately preceding lot, may be used as the value calculated in correspondence to the power setting indicated in a recipe having been used when processing a previous product substrate.

### (Dummy Decision-Making/Substrate Processing: Discontinuous Lot Feed)

Next, the dummy decision-making/substrate processing executed in conjunction with a discontinuous lot feed, which is called up in step 715, is explained in reference to the flowchart presented in FIG. 12. After the dummy decision-making/substrate processing for the discontinuous lot feed starts in step 1200 in FIG. 12, the operation proceeds to step 805 in which the decision-making unit 270 determines the setting selected for the dummy execution adjustment parameter.

### (Parameter; Discontinuous Lot Feed or Continuous/Discontinuous Lot Feed)

If either “discontinuous lot feed” or “continuous/discontinuous lot feed” has been selected for the dummy execution adjustment parameter, the decision-making unit 270 judges that the operator wishes to execute the dummy process unconditionally and, in this case, the operation proceeds to step 830.

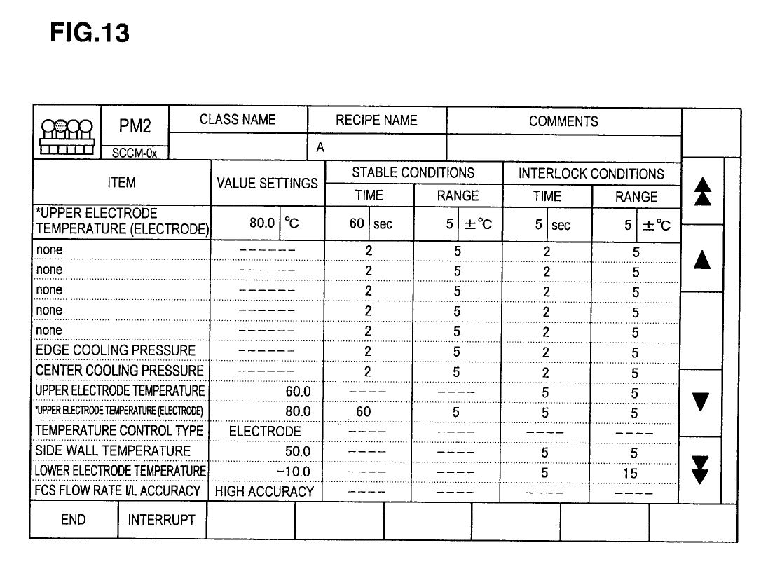

In this situation, even if the upper electrode temperature Tr indicated in the recipe to be used in the subsequent processing is equal to the detected temperature Tsen or the upper electrode temperature Tr indicated in the recipe (see the etching process recipe B in FIG. 10) to be used in the subsequent processing is equal to the upper electrode temperature Trold indicated in the recipe (see the etching process recipe A in FIG. 13) used for the immediately preceding processing, the dummy process execution unit 275 executes the dummy process on a dummy substrate in step 830, the substrate processing execution unit 280 executes and etching process on the substrates belonging to the current lot in step 820, the operation then proceeds to step 825 to save the recipe temperature Tr as the preceding recipe temperature Trold and subsequently, the operation proceeds to step 1295 to end the processing sequence.

### (Parameter: No Setting or Continuous Lot Feed)

If, on the other hand, it is decided in step 805 that the dummy execution adjustment parameter is set to “no setting” or “continuous lot feed”, the decision-making unit 270 makes a decision in step 815 following step 810 as to whether or not the third decision-making condition is satisfied. If it is decided in step 815 that the third decision-making condition is not satisfied, the decision-making unit judges that the dummy process needs to be executed and in this case, the dummy process is executed in step 830, and the etching process is executed in step 820. The operation then proceeds to step 825 to save the recipe temperature Tr as the preceding recipe temperature Trold. Subsequently, the operation proceeds to step 895 to end the processing sequence.

If it is decided in step 815 that the third decision-making condition is satisfied, the operation proceeds to step 1205 in which the decision-making unit 270 makes a decision as to whether or not the absolute value of the difference between the preceding recipe temperature Trold and the recipe temperature Tr is within the range indicated by the interlock Tsh2 (whether or not the first decision-making condition is satisfied).

If the absolute value of the difference between the preceding recipe temperature Trold and the recipe temperature Tr is within the range indicated by the interlock Tsh2, the decision-making unit 270 judges that the dummy process does not need to be executed and the operation proceeds to step 820. In step 820, the substrate processing execution unit 280 executes the etching process on the substrates. The recipe temperature Tr is saved as the preceding recipe temperature Trold in step 825, and then the operation proceeds to step 1295 to end the processing sequence.

If, on the other hand, it is decided in step 1205 that the absolute value of the difference between the preceding recipe temperature Trold and the recipe temperature Tr is greater than the interlock Tsh2, the decision-making unit 270 judges that the dummy process needs to be executed and the operation proceeds to step 830. After the dummy process and the etching process are executed in step 820, the operation proceeds to step 825 to save the recipe temperature Tr as the preceding recipe temperature Trold. Then the operation proceeds to step 1295 to end the processing sequence.

It is reasonable to assume that when lot processing is executed discontinuously, a relatively long period of time elapses between the processing time point at which the immediately preceding lot (product substrates) is processed and the processing time point at which the next lot is processed. Such a situation may arise when, for instance, a lot is fed into the substrate processing apparatus after conducting maintenance work. Under these circumstances, the states inside the processing container will have been disrupted and destabilized. For this reason, the states inside the processing container need to be regulated before processing product substrates. The temperature status, in particular, needs to be pre-controlled for the reasons explained earlier.

In the dummy decision-making/substrate processing executed in conjunction with the discontinuous lot feed in the embodiment described above, the dummy process is executed unconditionally if the selected parameter indicates the processing for the discontinuous lot feed (i.e., the parameter indicating “discontinuous lot feed” or “continuous/discontinuous lot feed”). Thus, the atmosphere inside the processing container can be stabilized with a high level of reliability prior to the product substrate processing.

In the dummy decision-making/substrate processing (continuous lot feed) shown in FIG. 8, a decision is made based upon the first decision-making condition in step 835, a decision is made based upon the second decision-making condition in step 840 and a decision is made based upon the third decision-making condition in step 815. In addition, in the dummy decision-making/substrate processing (discontinuous lot feed) shown in FIG. 12, a decision is made based upon the first decision-making condition in step 1205 and a decision is made based upon the third decision-making condition in step 815.

In other words, the decision-making unit 270 may make a decision based upon the second decision-making conditions or conditions including the second decision-making condition only when a continuous lot feed instruction is issued by the continuous lot feed instruction unit 260.

In addition, if a continuous lot feed instruction has been issued by the continuous lot feed instruction unit 260 but the selected parameter does not indicate the continuous lot feed as the dummy processing execution condition (i.e., if either “no setting” or “discontinuous lot feed” has been set as the parameter), the decision-making unit 270 may judge whether or not the temperature status in the processing container has been regulated by making a decision based upon the first decision-making condition in step 835, and making a decision based upon the second decision-making condition in step 840 but without making a decision based upon the third decision-making condition in step 815, in the processing shown in FIG. 8.

### (Variation 1 of the Substrate Processing Apparatus)

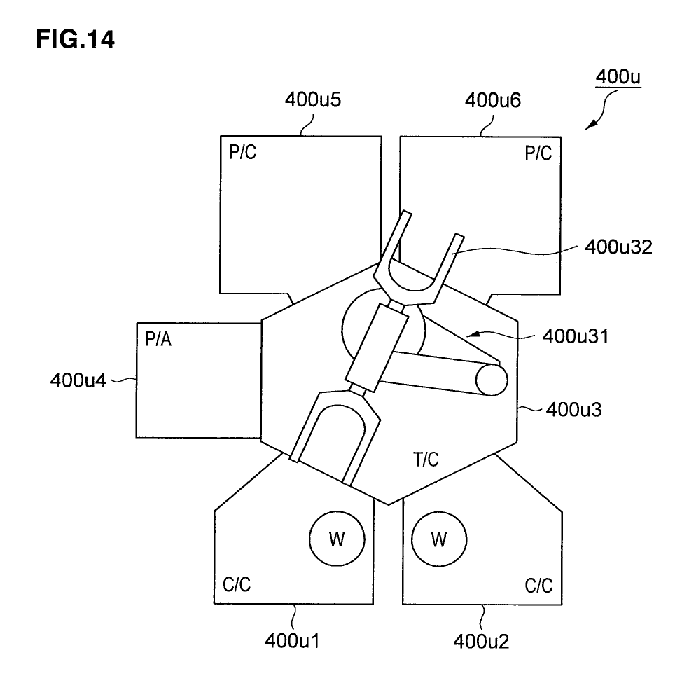

Substrate processing apparatuses may each adopt an alternative structure to that of the PM 400 shown in FIG. 3, such as the structure assumed in a PM 400u in FIG. 14. The PM 400u comprises cassette chambers (C/C) 400u1 and 400u2, a transfer chamber (T/C) 400u3, a pre-alignment mechanism (P/A) 400u4 and processing chambers (CP/C) (=PM) 400u5 and 400u6.

Unprocessed product substrates (wafers W) and processed product substrates are stored in the cassette chambers 400u1 and 400u2 and, in addition, three non-product substrates for dummy processing, for instance, are stored at the bottom stage in each cassette. The pre-alignment mechanism 400u4 positions each wafer W.

An articulated arm 400u31 capable of extending/bending and rotating is disposed in the transfer chamber 400 u3. The arm 400u31 transfers a wafer W held on a fork 400u32 located at an end of the arm 400u31, between the cassette chamber 400u1 or 400u2 and the pre-alignment mechanism 400u4 and between the pre-alignment mechanism 400u4 and the processing chamber 400u5 or 400u6, as it extends/bends and rotates as necessary.

A decision as to whether or not to execute the dummy process prior to the execution of the wafer processing such as etching in the processing chambers 400u5 and 400u6 may be made as explained earlier for the PM 400u adopting such a structure as well. Then, if it is decided that no dummy process needs to be executed, wafers W are transferred into the processing chambers 400 u5 and 400u6 without executing the dummy process and the transferred wafers W undergo the actual processing. When lots are fed discontinuously, however, the dummy process is invariably executed before executing the wafer processing such as etching on wafers W in the processing chambers 400u5 and 400u6.

### (Variation 2 of the Substrate Processing Apparatus)

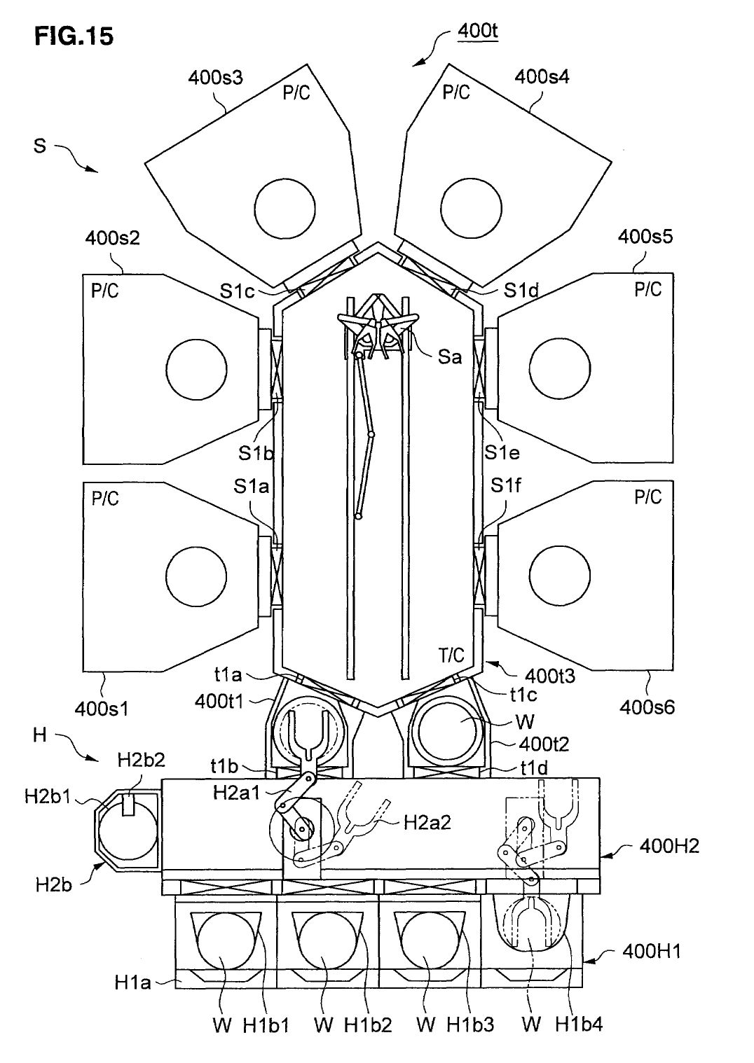

Alternatively, the substrate processing apparatuses may adopt the structure assumed in a PM 400t shown in FIG. 15. The PM 400t includes a transfer system H through which wafers W are transferred and a processing system S where substrate processing such as CVD processing or etching is executed on the wafers W. The transfer system H and the processing system S are connected with each other via load-lock chambers (LLMs: load-lock modules) 400t1 and 400t2.

The transfer system H includes a cassette stage 400H1 and a transfer stage 400H2. A container table H 1a is disposed at the cassette stage 400H1, and four cassette containers H1b1˜H1b4 are set on the container table H1a. In each cassette container H1b, unprocessed product substrates (wafers W), processed product substrates and non-product substrates used in dummy processing can be stored over multiple stages.

At the transfer stage 400H2, two transfer arms H2a1 and H2a2 capable of extending/bending and rotating are supported so as to be allowed to slide through magnetic drive. A wafer W is held on a fork mounted at the front end of each of the transfer arms H2a1 and H2a2.

An alignment mechanism H2b that positions a wafer W is disposed at one end of the transfer stage 400H2. The alignment mechanism H2b adjusts the position of the wafer W by detecting via an optical sensor H2b2 the peripheral edge of the wafer W placed on a rotating table H2b1.

Inside each load lock chamber 400t1 and 400t2, a stage on which a wafer W is placed is disposed. In addition, gate valves t1a and t1b and gate valves t1c and t1d that can be opened/closed while sustaining airtightness are respectively disposed at the two ends of the load lock chamber 400t1 and the load lock chamber 400t2. The transfer system H adopting the structure described above transfers wafers W between the cassette containers H1b1˜H1b4 and the load lock chambers 400t1 and 400t2 and the alignment mechanism H2b.

The processing system S includes a transfer chamber (T/C) 400t3 and six processing chambers (P/C) 400s1˜400s6 (=PM1˜PM6). The transfer chamber 400t3 is connected with the processing chambers 400s1˜400s6 respectively via gate valves s1a˜s1f that can be opened/closed while sustaining airtightness. An arm Sa capable of extending/bending and rotating is disposed in the transfer chamber 400t3.

In the processing system adopting the structure described above, wafers W transferred on the arm Sa from the load lock chambers 400t1 and 400t2 into the processing chambers 400s1 ˜400s6 via the transfer chamber 400t3 undergo wafer processing such as etching, and the processed wafers are then transferred back into the load lock chambers 400t1 and 400t2 via the transfer chamber 400t3.

A decision as to whether or not to execute the dummy process prior to the execution of the wafer processing such as etching in the processing chambers 400s1˜400s6 may be made as explained earlier for the PM 400t adopting such a structure as well. Then, if it is decided that no dummy process needs to be executed, wafers W are transferred into the processing chambers 400s1˜400s6 without executing the dummy process and the transferred wafers W undergo the actual processing. When lots are fed discontinuously, however, the dummy process is invariably executed before executing the wafer processing such as etching on wafers W in the processing chambers 400s1˜400s6.

The operations of the individual units, executed in the embodiment as described above, are correlated and thus, they may be regarded as a series of operations by bearing in mind how they relate to one another. By considering them as a sequence of operations, the embodiment of the control device for the substrate processing apparatus according to the present embodiment of the invention can be remodeled as a control method to be adopted when controlling a substrate processing apparatus.

In addition, by translating the operations executed in the individual units of the control device described above to processing at the individual units, the present embodiment of the invention can be embodied as a program to be used to control a substrate processing apparatus. By storing this substrate processing apparatus control program in a computer-readable recording medium, the embodiment of the control program can be remodeled into an embodiment of a computer-readable recording medium having recorded therein the control program.

While the invention has been particularly shown and described with respect to preferred embodiments thereof by referring to the attached drawings, the present invention is not limited to these examples and it will be understood by those skilled in the art that various changes in form and detail may be made therein without departing from the spirit, scope and teaching of the invention.

For instance, the present invention may be adopted in conjunction with any type of substrate processing apparatuses including a capacitively-coupled plasma processing apparatus, an inductively-coupled plasma processing apparatus and a microwave plasma processing apparatus. In addition, the present invention may be adopted in a substrate processing apparatus that processes regular wafer-size substrates, as well as a substrate processing apparatus that processes a large glass substrate.

Furthermore, the present invention may be adopted in substrate processing apparatuses in which any type of substrate processing, including thermal diffusion processing, ashing and sputtering, as well as film formation and etching, is executed.

Moreover, the functions of the control device according to the present invention can be embodied in at least either the EC 200 or the MC 300.

What is claimed is:

1. A control device for a substrate processing apparatus comprising:
a substrate processing execution unit that executes a predetermined processing on a product substrate;
a dummy processing execution unit that executes dummy processing on a non-product substrate; and
a decision-making unit that obtains information related to a temperature to be used to regulate the atmosphere within a processing container included in the substrate processing apparatus and makes a decision as to whether or not a temperature status within the processing container is already regulated based upon the obtained temperature information, wherein:
the substrate processing execution unit executes the predetermined processing on the product substrate without allowing the dummy processing execution unit to execute the dummy processing in case that the decision-making unit determines that the temperature status in the processing container is already regulated.

2. The control device for a substrate processing apparatus according to claim 1, further comprising:
a storage unit in which a single recipe or a plurality of recipes to be used when processing substrates are stored, wherein:
the decision-making unit makes a decision as to whether or not the temperature status in the processing container is regulated based upon a first decision-making condition for comparing a temperature setting indicated in a recipe used when processing an immediately preceding product substrate with a temperature setting indicated in a recipe to be used in the next product substrate among the recipes stored in the storage unit.

3. The control device for a substrate processing apparatus according to claim 2, wherein:
the decision-making unit makes a decision as to whether or not the temperature status in the processing container is regulated based upon a second decision-making condition for comparing a value calculated in correspondence to a power setting indicated in a recipe used when processing a previous product substrate with a value of a power setting indicated in a recipe to be used when processing the next product substrate in addition to the first decision-making condition.

4. The control device for a substrate processing apparatus according to claim 1, wherein:
the substrate processing apparatus includes a temperature sensor that detects the temperature inside the processing container; and
the decision-making unit obtains the temperature inside the processing container detected by the temperature sensor and makes a decision as to whether or not the temperature status in the processing container is regulated based upon a third decision-making condition for comparing the obtained temperature in the processing container with the temperature setting indicated in a recipe to be used when processing the next product substrate.

5. The control device for a substrate processing apparatus according to claim 3, further comprising:
a continuous lot feed instruction unit that issues a continuous lot feed instruction so as to allow a second lot constituted with another product substrate group to be continuously processed in succession to a first lot constituted with a product substrate group that includes a product substrate undergoing processing, wherein:
the decision-making unit makes a decision based upon the second decision-making condition or conditions including the second decision-making condition, when the continuous lot feed instruction unit has issued a continuous lot feed instruction.

6. The control device for a substrate processing apparatus according to claim 1, further comprising:
a discontinuous lot feed instruction unit that issues a discontinuous lot feed instruction so as to discontinuously execute processing for a given lot when a lot constituted with a product substrate group that includes a product substrate undergoing processing does not exist, wherein:
the dummy processing execution unit executes dummy processing on a non-product substrate before the predetermined processing is executed on product substrates in the discontinuously fed lot, without allowing the decision-making unit to make the decision in case that a discontinuous lot feed instruction is issued by the discontinuous lot feed instruction unit.

7. The control device for a substrate processing apparatus according to claim 4, wherein:
the decision-making unit makes a decision as to whether or not the temperature status inside the processing container is regulated based upon at least any one of decision-making condition among the first decision-making condition, the second decision-making condition and the third decision-making condition in correspondence to a parameter indicating a specified dummy processing execution condition.

8. The control device for a substrate processing apparatus according to claim 7, wherein:
the decision-making unit makes a decision as to whether or not the temperature status inside the processing container is regulated based upon the third decision-making condition in case that a continuous lot feed instruction is issued by the continuous lot feed instruction unit and “continuous lot feed” is specified in the parameter as the dummy processing execution condition.

9. The control device for a substrate processing apparatus according to claim 7, wherein:
the decision-making unit makes a decision as to whether or not the temperature status in the processing container is regulated based upon the first decision-making condition and the second decision-making condition in case that a continuous lot feed instruction is issued by the continuous lot feed instruction unit and “continuous lot feed” is not specified in the parameter as the dummy processing execution condition.

10. The control device for a substrate processing apparatus according to claim 7, wherein:
if a continuous lot feed instruction is issued by the continuous lot feed instruction unit and “continuous lot feed” is not specified in the parameter as the dummy processing execution condition, the decision-making unit makes a decision as to whether or not the temperature status in the processing container is regulated based upon the first decision-making condition, the second decision-making condition and the third decision-making condition.

11. The control device for a substrate processing apparatus according to claim 7, wherein:
the dummy processing execution unit executes dummy processing on a non-product substrate before executing the predetermined processing on the discontinuously fed product substrates without allowing the decision-making unit to make the decision in case that a discontinuous lot feed instruction is issued by the discontinuous lot feed instruction unit and “discontinuous lot feed” is specified in the parameter as the dummy processing execution condition.

12. The control device for a substrate processing apparatus according to claim 7, wherein:
the dummy processing execution unit makes a decision as to whether or not the temperature status inside the processing container is regulated based upon the first decision-making condition and the third decision-making condition in case that a discontinuous lot feed instruction is issued by the discontinuous lot feed instruction unit and “discontinuous lot feed” is not specified in the parameter as a dummy processing execution condition.

13. A control method to be adopted when controlling a substrate processing apparatus that executes a predetermined processing on a product substrate, comprising:
obtaining temperature-related information to be used to regulate the atmosphere inside a processing container;
making a decision as to whether or not a temperature status inside the processing container is regulated based upon the obtained temperature information; and
executing the predetermined processing on a product substrate without executing dummy processing on a non-product substrate in case that the temperature status inside the processing container is decided to be regulated.

14. A computer-readable recording medium having stored therein a control program in conformance to which a substrate processing apparatus that executes a predetermined processing on a product substrate is controlled, with the control program enabling a computer to execute:
a module for obtaining temperature-related information to be used to regulate the atmosphere inside a processing container;
a module for making a decision as to whether or not a temperature status inside the processing container is regulated based upon the obtained temperature information; and
a module for executing the predetermined processing on a product substrate without executing dummy processing on a non-product substrate in case that the temperature status inside the processing container is decided to be regulated.
